(19) United States
(12) Patent Application Publication
(10) Pub. No.: US 2024/0162902 A1
(43) Pub. Date: May 16, 2024

(54) ELECTRONIC WAVE SWITCH

(71) Applicant: Pass & Seymour, Inc., Syracuse, NY (US)

(72) Inventor: Clayton Roberts, Tully, NY (US)

(73) Assignee: Pass & Seymour, Inc., Syracuse, NY (US)

(21) Appl. No.: 17/984,695

(22) Filed: Nov. 10, 2022

(51) Int. Cl. H03K 17/945; G01S 17/04; H05K 1/18

(52) U.S. Cl. CPC H03K 17/945; G01S 17/04; H05K 1/181; H03K 2217/945; H05K 2201/10151

(57) ABSTRACT

An electronic wave switch device for controlling a load, the device comprising: a housing assembly including a front cover assembly having a user interface, a back body assembly dimensioned to fit within a standard sized NEMA wall box, and a plurality of terminals configured to be coupled to an AC power source and the load a mounting strap for connection to the standard sized NEMA wall box; and a circuit assembly disposed inside the housing assembly coupled to the plurality of terminals, the circuit assembly comprising a printed circuit board, the printed circuit board including a sensor coupled to a processor, wherein the sensor is configured to receive and detect an input stimulus in response to movement of an object a predetermined distance from the sensor, and wherein the processor is configured to propagate a switch actuation command in response to detecting the input stimulus.

### BACKGROUND OF THE INVENTION

### 1. Field of the Invention

This disclosure is related, generally, to electronic switching, and, more specifically, to an electronic wave switch that can be installed within a standard sized wall box.

### BRIEF SUMMARY OF THE INVENTION

The examples described herein can be combined in any way technically possible.

According to an aspect, an electronic wave switch device for controlling a load, the device comprising: a housing assembly including a front cover assembly having a user interface, a back body assembly dimensioned to fit within a standard sized NEMA wall box, and a plurality of terminals configured to be coupled to an AC power source and the load; a mounting strap for connection to the standard sized NEMA wall box; and a circuit assembly disposed inside the housing assembly coupled to the plurality of terminals, the circuit assembly comprising a printed circuit board, the printed circuit board including a sensor coupled to a processor, wherein the sensor is configured to receive and detect an input stimulus in response to movement of an object a predetermined distance from the sensor, and wherein the processor is configured to propagate a switch actuation command in response to detecting the input stimulus.

In an example, the printed circuit board further includes a signal emitter configured to emit a predetermined signal.

In an example, the sensor includes a photo-sensitive element configured to measure light reflected from the signal emitter by the object wherein the signal emitter is a light emitting diode (LED).

In an example, the sensor is configured to detect light of a predetermined frequency.

In an example, the light emitted from the LED is infrared light.

In an example, the electronic wave switch further includes a ground wire, wherein the ground wire extends through a back body assembly and extends through the mounting strap.

### BRIEF DESCRIPTION OF THE SEVERAL VIEWS OF THE DRAWING(S)

The present invention will be more fully understood and appreciated by reading the following Detailed Description in conjunction with the accompanying drawings.

FIG. 1 depicts a perspective view of an electronic wave switch, according to an example.

FIG. 2 depicts a perspective view of an electronic wave switch without an aesthetic cover, according to an example.

FIG. 3 depicts an exploded view of an electronic wave switch, according to an example.

FIG. 4, depicts a perspective view of an AC power circuit, according to an example.

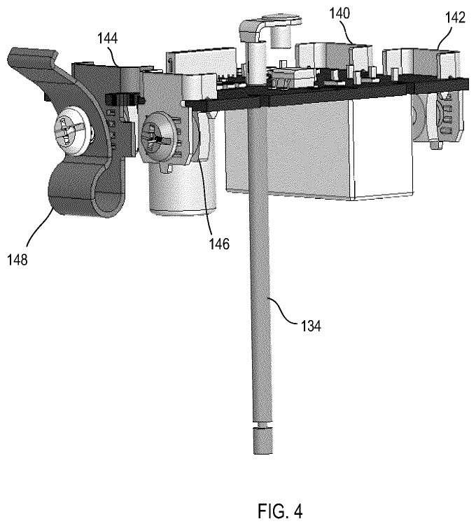

FIG. 5 depicts a perspective view of an electronic actuator circuit, according to an example.

FIG. 6 depicts a perspective view of a mounting strap, according to an example.

### DETAILED DESCRIPTION OF THE INVENTION

Aspects of the various examples and certain features, advantages, and details thereof, are explained more fully below with reference to the non-limiting examples illustrated in the accompanying drawings. Descriptions of well-known structures are omitted so as not to unnecessarily obscure the invention in detail. It should be understood, however, that the detailed description and the specific non-limiting examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Reference will now be made in detail to the present exemplary embodiments of the invention, examples of which are illustrated in the accompanying drawings. Wherever possible, the same reference numbers will be used throughout the drawings to refer to the same or like parts. Various parts/elements of the protective device of embodiments of the present invention are first identified below and illustrated in the accompanying drawings. Many of the parts/elements are conventional, should be understood by a person of ordinary skill in the art in conjunction with a review of this disclosure, and are not necessarily further discussed in detail beyond being identified and represented in certain Figures. The structure, configuration, and positioning with respect to other particular parts/elements/assemblies in the assembled protective wiring device as a whole, and/or functionality of other particular parts/elements/assemblies are unique and inventive. Such other parts/elements/assemblies are described in further detail below in addition to the being identified and represented in certain Figures.

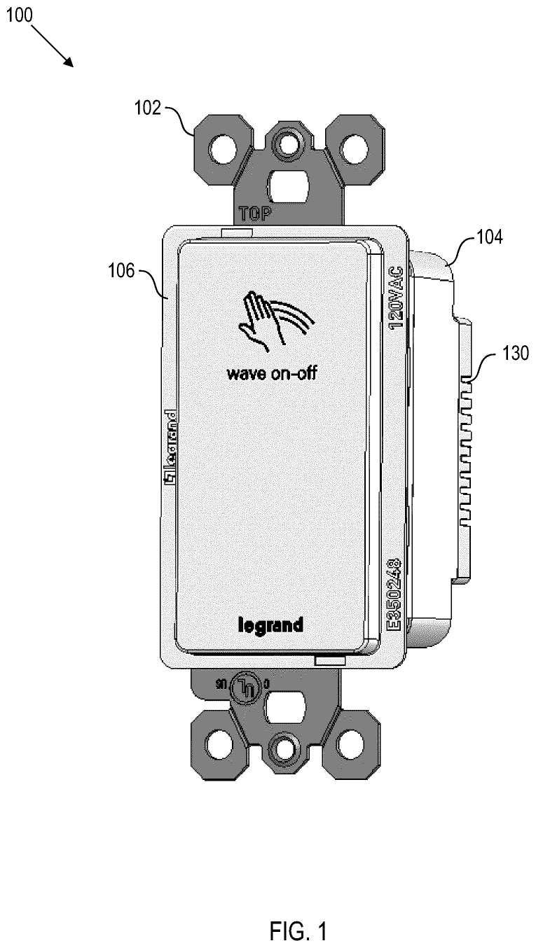

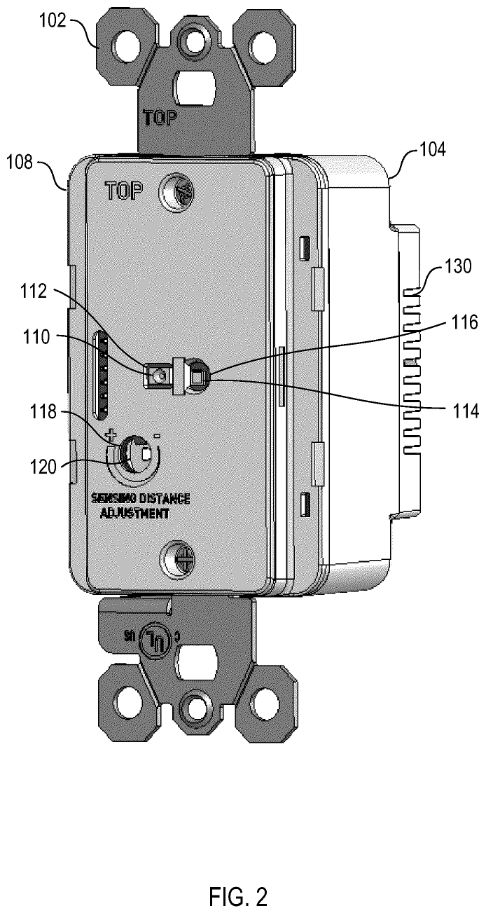

FIG. 1 depicts a perspective view of an example electronic wave switch 100 having a mounting strap 102 and a back body 104 being dimensioned to fit within a standard (NEMA) sized wall box. An aesthetic cover portion 106 can be attached to an enclosure portion 108, which is shown in more detail in FIG. 2. Enclosure portion 108 mates with the back body 104 to form a device housing enclosing the internals of wave switch 100. An infrared (“IR”) lens 110 is disposed to extend through, or to otherwise emit infrared light through, infrared lens aperture 112 defined in enclosure portion 108. Similarly, an infrared sensor 114 is positioned to extend through, or to otherwise receive infrared light through, infrared sensor aperture 116. A sensor adjustment aperture 118 is formed in enclosure portion 108 and accommodates adjustment of the sensor adjustor 120.

During operation, infrared lens 110 passes infrared light, emitted by an infrared LED D100, at a predetermined frequency. Infrared sensor 114 is configured to detect the predetermined frequency of infrared light, such that, a user, waving a hand in front of the infrared lens 110 will reflect the light of predetermined frequency to be detected by infrared sensor 114. A detection of the predetermined frequency will actuate the switch (e.g., change from an ON to an OFF position or from an OFF to an ON position). Sensor adjustor 120 adjusts the sensitivity of infrared sensor 114, and, consequently, the distance that a hand in front of infrared sensor 114 can be detected.

The size of the infrared LED aperture 112 encloses and isolates the infrared LED D100 from the other components. The infrared LED aperture 112 also prevents the infrared light that is emitted from the LED D100 from interfering with the infrared sensor 114 (U102). Stated differently, LED aperture 112 allows the LED light to be emitted into the ambient space around the device 100, but it also prevents infrared light from bleeding through the plastic in the enclosure to inadvertently cause the infrared sensor 114 to actuate the switch. On the other hand, the sensor opening 116 is also important. If the opening size is too small, the amount of reflected light is limited such that the amount of light directed to the sensor is not sufficient to effect a desired switch actuation (hand wave). If the opening is too large, internal infrared light may be reflected by the lens 1112 and inadvertently actuate the switch. In sum, the opening 116 maximizes the sensor viewing angle of the sensor 114 to optimize its ability to sense reflected infrared light (i.e., from a hand wave).

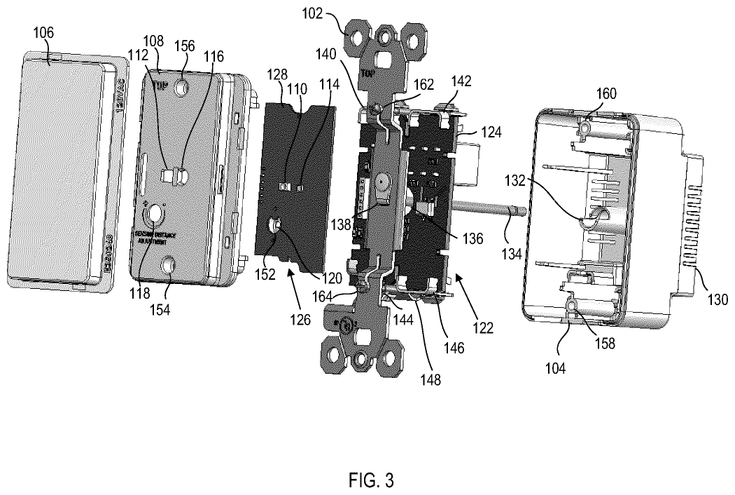

Referring to FIG. 3, an exploded view of the electronic wave switch 100 depicted in FIGS. 1 and 2 is disclosed. The electronic wave switch device 100 includes an AC power circuit 122 (disposed on printed circuit board 124) disposed within the back body 104. The AC power circuit 122 provides power to an electronic actuator circuit 126 (disposed on printed circuit board 128) that is disposed in the wave switch actuator assembly. In this example, the electronic actuator circuit 124 is spaced apart from the AC power circuit 122. The back body 104 and the AC power circuit 122 are identical for each of the embodiments disclosed herein. AC power circuit 122 can be implemented as any suitable circuit for powering electronic actuator circuit 126. Similarly, electronic actuator circuit 126 can be implemented as any suitable circuit for operating LED D100, infrared sensor 114 and for actuating the switch in response to detecting the reflected infrared light, as described above. A suitable AC power circuit an electronic actuator circuit are described in detail in US 2021/0020396 titled “Electronic Switching Device and System” and incorporated herein by reference in its entirety.

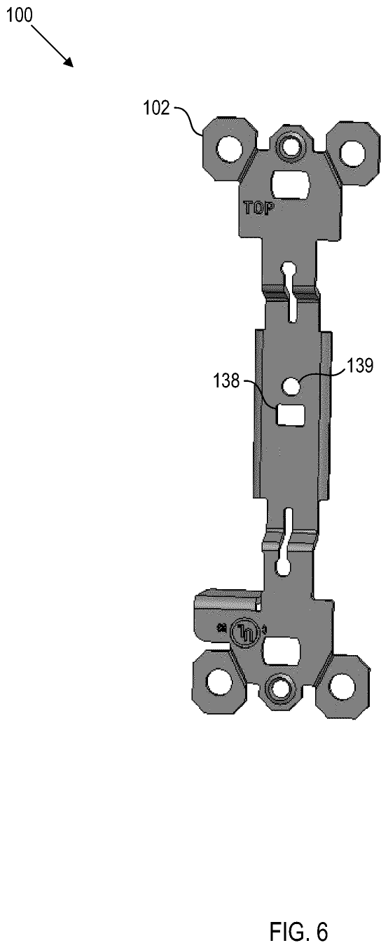

The back body 104 includes heat dissipation vents 130 that allow thermal energy generated by the electronics to vent and dissipate. The back body 104 includes a ground wire tube 132 that is formed in the center portion thereof. The ground wire tube 132 is configured to accommodate a ground wire 134 that extends through the center portion of the device 100 through opening 136 in PCB 124 and opening 138 in mounting strap 102, ground wire 134 contacting mounting strap 102 at attachment point 139 (FIG. 6 shows mounting strap 102 and opening 138 in greater detail.) The back body 104 also includes ribbing of various shapes and sizes that accommodate and space apart the printed circuit boards (PCBs 124, 128).

A plurality of terminal structures (140, 142, 144, 146) are connected to the PCB 124 around its periphery. Additionally, a ground clip 148 provides the power supply return path with a selectable “earth link” to a frame or to a neutral wire. Examples, including various suitable alternative examples, of such a ground clip are described in U.S. Pat. No. 11,387,608 titled “Electrical wiring device with flexible terminal for eliminating connection to ground,” incorporated herein by reference in its entirety. As will be understood by a person of ordinary skill in the art, the plurality of terminal structure provide for connection to a source of AC power and for connection to a load, the actuation of the switch interrupting or, alternately, permitting the flow of current from the AC power source to the load. The load can be any suitable type of load that a switch can actuate, including a light, a motor (e.g., a garbage disposal), a fireplace or furnace, etc.

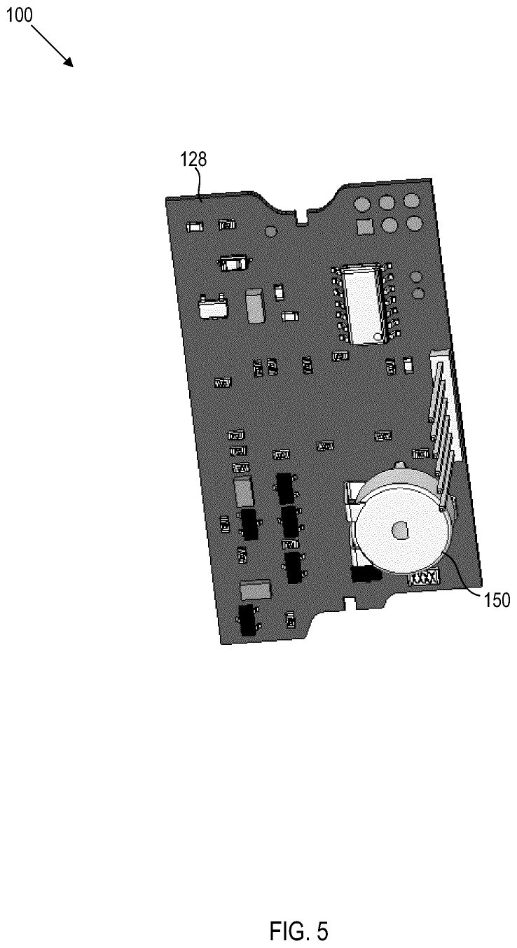

Sensor adjustor 120 is coupled to a potentiometer 150 (R115) (shown in FIG. 5), mounted on PCB 128. Sensor adjustor 120 is accessible through aperture 152. The potentiometer 150 controls the sensitivity of the sensor 114 (U102), which is also mounted on PCB 128. Infrared LED D100 is also mounted on the PCB 128 adjacent to the sensor 114 (U102). The sensor adjustment aperture 152 can include a limiter portion that prevents the sensor adjustor 120 from being over-rotated (such that potentiometer 150 is damaged). The potentiometer 150 can include a keyed opening for a longitudinal portion of the sensor adjustor 120.

FIG. 3 additionally demonstrates that enclosure portion 108 can be mated together with back body 104 with fasteners, such as screws, that are received through openings 154 and 156 in enclosure portion 108 and mate with threaded aperture 158 and 160 in back body 104. Fasteners can be further received through openings 162 and 164 in mounting strap 102.

Wave switch 100 can further be configured to receive a wall plate, e.g., through a snap attachment. Such a wall plate is described in greater detail in U.S. Pat. No. 10,279,235 titled “Modular Electrical Wiring Device System” and in US 2020/00185898 titled “Modular electrical wiring device assembles,” both of which are hereby incorporated by reference in their entirety.

All references, including publications, patent applications, and patents, cited herein are hereby incorporated by reference to the same extent as if each reference were individually and specifically indicated to be incorporated by reference and were set forth in its entirety herein.

All definitions, as defined and used herein, should be understood to control over dictionary definitions, definitions in documents incorporated by reference, and/or ordinary meanings of the defined terms.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

The recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

What is claimed is:

1. An electronic wave switch device for controlling a load, the device comprising:
a housing assembly including a front cover assembly having a user interface, a back body assembly dimensioned to fit within a standard sized NEMA wall box, and a plurality of terminals configured to be coupled to an AC power source and the load
a mounting strap for connection to the standard sized NEMA wall box; and
a circuit assembly disposed inside the housing assembly coupled to the plurality of terminals, the circuit assembly comprising a printed circuit board, the printed circuit board including a sensor coupled to a processor, wherein the sensor is configured to receive and detect an input stimulus in response to movement of an object a predetermined distance from the sensor, and wherein the processor is configured to propagate a switch actuation command in response to detecting the input stimulus.

2. The electronic wave switch device of claim 1, wherein the printed circuit board further includes a signal emitter configured to emit a predetermined signal.

3. The electronic wave switch device of claim 2, wherein the sensor includes a photo-sensitive element configured to measure light reflected from the signal emitter by the object wherein the signal emitter is a light emitting diode (LED).

4. The electronic wave switch device of claim 3, wherein the sensor is configured to detect light of a predetermined frequency.

5. The electronic wave switch device of claim 3, wherein the light emitted from the LED is infrared light.

6. The electronic wave switch device of claim 1, further comprising a ground wire, wherein the ground wire extends through a back body assembly and extends through the mounting strap.
